(19) United States
(12) Patent Application Publication
(10) Pub. No.: US 2025/0079256 A1
(43) Pub. Date: Mar. 6, 2025

(54) THERMALLY CONDUCTIVE GRAPHENE PAD BORDERED WITH PROTECTIVE FILM AND PREPARATION METHOD THEREFOR

(71) Applicant: Suzhou Nanyi Technology Co., LTD, Suzhou (CN)

(72) Inventor: Nan WANG, Suzhou (CN)

(73) Assignee: Suzhou Nanyi Technology Co., LTD, Suzhou (CN)

(21) Appl. No.: 18/824,103

(22) Filed: Sep. 4, 2024

Related U.S. Application Data
(63) Continuation of application No. PCT/CN2024/098555, filed on Jun. 12, 2024.

(30) Foreign Application Priority Data
Sep. 4, 2023 (CN) 2023111271078

(51) Int. Cl. H01L 23/373; H01L 23/00; H01L 23/367

(52) U.S. Cl. CPC H01L 23/373; H01L 23/3672; H01L 24/32; H01L 2224/32245

(57) ABSTRACT

The present disclosure provides a thermally conductive graphene pad bordered with a protective film, including a thermally conductive graphene pad body and the protective film, wherein peripheries of side surfaces of the thermally conductive graphene pad body are covered with the protective film; or edges of an upper surface of the thermally conductive graphene pad body, edges of a lower surface of the thermally conductive graphene pad body, and side surfaces of the thermally conductive graphene pad body are covered with the protective film; or edges of one surface of the thermally conductive graphene pad body and side surfaces of the thermally conductive graphene pad body are covered with the protective film.

### CROSS-REFERENCE TO RELATED APPLICATIONS

The application claims priority to Chinese patent application No. 2023111271078, filed on Sep. 4, 2023, the entire contents of which are incorporated herein by reference.

### TECHNICAL FIELD

The present disclosure relates to a thermally conductive graphene pad bordered with a protective film and a preparation method therefor.

### BACKGROUND

With the rapid development of various electronic products, the performance of electronic components has experienced a fast development. At present, with improved performance, these electronic components also contribute to an increase in the heat generation of devices. For example, the high brightness of a display screen increases the use of light-emitting diodes and puts forward higher requirements for its frequency, the high-speed operation of a CPU increases the consumption of battery power, so that the battery capacity also needs to be increased, and so on. During the high-speed operation of the electronic components, higher energy consumption and faster heat generation put forward higher requirements for heat dissipation components. If the heat cannot be dissipated in time, the service life of a device will be shortened.

### SUMMARY

To solve the technical problems described above, an object of the present disclosure is to provide a thermally conductive graphene pad bordered with a protective film and a preparation method for the same.

To solve the technical problems described above, the present disclosure provides a technical solution as follows: a thermally conductive graphene pad bordered with a protective film includes a thermally conductive graphene pad body and the protective film covering the thermally conductive graphene pad body.

In some embodiments, the thermally conductive graphene pad body includes longitudinally arranged graphene, which runs through upper and lower surfaces of the thermally conductive graphene pad body to form a thermally conductive continuous structure.

In some embodiments, the protective film is a monolithic protective film.

In some embodiments, the protective film is a homocentric square-shaped monolithic protective film.

In some embodiments, peripheries of side surfaces of the thermally conductive graphene pad body are covered with the protective film.

In some embodiments, the protective film is formed from cured polyurethane, polysiloxane, styrene-butadiene latex, paraffin, polyethylene terephthalate, epoxy resin, polyethylene, acrylic resin, or polyimide.

In some embodiments, edges of the upper surface of the thermally conductive graphene pad body, edges of the lower surface of the thermally conductive graphene pad body, and side surfaces of the thermally conductive graphene pad body are covered with the protective film.

In some embodiments, the homocentric square-shaped monolithic protective film has an overall width equal to the width of the thermally conductive graphene pad body to be bordered with the protective film*2+ the thickness of the thermally conductive graphene pad body.

In some embodiments, edges of one surface of the thermally conductive graphene pad body and side surfaces of the thermally conductive graphene pad body are covered with the protective film, and the other surface of the thermally conductive graphene pad body is laminated to an application substrate by means of the protective film extending to a surface of the application substrate.

In some embodiments, the homocentric square-shaped monolithic protective film has an overall width equal to the width of the thermally conductive graphene pad body to be bordered with the protective film + the thickness of the thermally conductive graphene pad body + the lamination width of the protective film to the application substrate.

In some embodiments, for two edges of the thermally conductive graphene pad body in a direction of the graphene orientation, the thermally conductive graphene pad body is bordered with the protective film at:
an upper surface of the thermally conductive graphene pad body at the edges in the direction of the graphene orientation;
a lower surface of the thermally conductive graphene pad body at the edges in the direction of the graphene orientation;
and two side surfaces of the thermally conductive graphene pad body in the direction of the graphene orientation;
for two edges of the thermally conductive graphene pad body in a direction perpendicular to the graphene orientation, the thermally conductive graphene pad body is bordered with the protective film at:
an upper surface of the thermally conductive graphene pad body at the edges in the direction perpendicular to the graphene orientation;
and two side surfaces of the thermally conductive graphene pad body in the direction perpendicular to the graphene orientation; and
a lower surface of the thermally conductive graphene pad body at the edges in the direction perpendicular to the graphene orientation is laminated to the application substrate.

In some embodiments, for the two edges of the thermally conductive graphene pad body in the direction of the graphene orientation, a width of the homocentric square-shaped monolithic protective film in the direction of the graphene orientation is equal to the width of the thermally conductive graphene pad body to be bordered with the protective film*2+ the thickness of the thermally conductive graphene pad body; and a width of the homocentric square-shaped monolithic protective film to be used on the edges and side surfaces of the thermally conductive graphene pad body in the direction perpendicular to the graphene orientation and on the application substrate is equal to the width of the thermally conductive graphene pad body to be bordered with the protective film + the thickness of the thermally conductive graphene pad body + the lamination width of the protective film to the application substrate.

In some embodiments, the protective film has a thickness in a range of 1-30 microns.

In some embodiments, an area of one surface of the thermally conductive graphene pad body covered by the protective film accounts for 0.0%-30% of an area of the surface of the thermally conductive graphene pad body.

In some embodiments, a region of the thermally conductive graphene pad body covered by the protective film is as thick as a region of the thermally conductive graphene pad body uncovered by the protective film.

In some embodiments, the protective film has a tensile strength greater than that of the thermally conductive graphene pad body.

In some embodiments, the protective film has an elongation smaller than that of the thermally conductive graphene pad body under the same tensile force.

In some embodiments, a binding force of the protective film to the thermally conductive graphene pad body is greater than or equal to 100 g/25 mm.

To solve the above technical problems, the present disclosure further discloses a preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body to expose the thermally conductive graphene pad body to be bordered with the protective film to obtain the section A, wherein the area of the limiting device is smaller than or equal to that of the thermally conductive graphene pad body;
step (2), preparing section B: prefabricating the protective film on a release liner, cutting the protective film with the release liner to acquire a protective film frame having a shape and dimension matching the thermally conductive graphene pad body to be bordered with the protective film;
step (3), covering edges of one surface of the thermally conductive graphene pad body with the protective film frame;
step (4), covering side surfaces and edges of the other surface of the thermally conductive graphene pad body with the protective film frame; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

In some embodiments, the step (3) for covering the edges of one surface of the thermally conductive graphene pad body with the protective film frame includes: transferring the section B to one surface of the section A to allow a surface of the protective film of the section B to face one surface of the thermally conductive graphene pad body of the section A, and aligning and laminating the protective film of the section B to the section A in a manner of exposing the thermally conductive graphene pad body to be bordered with the protective film.

In some embodiments, the step (4) for covering the side surfaces and the edges of the other surface of the thermally conductive graphene pad body with the protective film frame includes: pressing down and laminating the protective film to the section A in a manner of exposing side surfaces of the thermally conductive graphene pad body to be bordered with the protective film, and then, bending the protective film towards the other surface of the thermally conductive graphene pad body to laminate to the other surface of the thermally conductive graphene pad body of the section A.

In some embodiments, the thermally conductive graphene pad body with the edges to be covered with the protective film in step (1) includes:
edges of the upper surface of the thermally conductive graphene pad body,
edges of the lower surface of the thermally conductive graphene pad body,
and peripheries of side surfaces of the thermally conductive graphene pad body.

In some embodiments, in step (2), the protective film of the section B is cut to form a homocentric square-shaped protective film on a surface of the release liner of the section B.

In some embodiments, the homocentric square-shaped protective film has a width equal to the width of the thermally conductive graphene pad body to be bordered with the protective film*2+ the thickness of the thermally conductive graphene pad body.

In some embodiments, the thermally conductive graphene pad body with the edges to be covered with the protective film in step (1) includes:
edges of the upper surface of the thermally conductive graphene pad body, and
peripheries of side surfaces of the thermally conductive graphene pad body; and
the protective film further covers a surface of the application substrate.

To solve the above technical problems, the present disclosure further discloses a preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body to expose the thermally conductive graphene pad body to be bordered with the protective film to obtain the section A, wherein the area of the limiting device is smaller than or equal to that of the thermally conductive graphene pad body;
step (2), preparing section B: prefabricating the protective film on a release liner, cutting the protective film with the release liner to acquire a protective film frame having a shape and dimension matching the thermally conductive graphene pad body to be bordered with the protective film;
step (3), covering edges of one surface of the thermally conductive graphene pad body with the protective film frame;
step (4), covering side surfaces of the thermally conductive graphene pad body with the protective film frame, pressing down and laminating the protective film 2 to the section A in a manner of exposing side surfaces of the thermally conductive graphene pad body 1 to be bordered with the protective film, then bending the protective film outwards to keep parallel to a surface of an application substrate, and then laminating the protective film to the surface of the application substrate; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

In some embodiments, in step (2), the protective film frame obtained after cutting is a homocentric square-shaped monolithic protective film, a width of which is equal to the width of the thermally conductive graphene pad body to be bordered with the protective film + the thickness of the thermally conductive graphene pad body + the lamination width to the application substrate.

To solve the above technical problems, the present disclosure further discloses a preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body to expose the thermally conductive graphene pad body to be bordered with the protective film to obtain the section A, wherein the area of the limiting device is smaller than or equal to that of the thermally conductive graphene pad body;
step (2), preparing section B: prefabricating the protective film on a release liner, cutting the protective film with the release liner to acquire a protective film frame having a shape and dimension matching the thermally conductive graphene pad body to be bordered with the protective film;
step (3), for two edges of the thermally conductive graphene pad body 1 in a direction of a graphene orientation, sequentially covering, with the protective film:
an upper surface of the thermally conductive graphene pad body at the edges in the direction of the graphene orientation;
side surfaces of the thermally conductive graphene pad body in the direction of the graphene orientation, and
a lower surface of the thermally conductive graphene pad body at the edges in the direction of the graphene orientation;
step (4), for two edges of the thermally conductive graphene pad body in a direction perpendicular to the graphene orientation, sequentially covering, with the protective film:
an upper surface of the thermally conductive graphene pad body at the edges in the direction perpendicular to the graphene orientation;
and side surfaces of the thermally conductive graphene pad body in the direction perpendicular to the graphene orientation, wherein
a lower surface of the thermally conductive graphene pad body at the edges in the direction perpendicular to the graphene orientation is laminated to the application substrate; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

In some embodiments, in step (2), the protective film frame obtained after cutting is a homocentric square-shaped monolithic protective film, and for the two edges of the thermally conductive graphene pad body in the direction of the graphene orientation, a width of the homocentric square-shaped monolithic protective film in the direction of the graphene orientation is equal to the width of the thermally conductive graphene pad body to be bordered with the protective film*2+ the thickness of the thermally conductive graphene pad body.

In some embodiments, in step (2), the protective film frame obtained after cutting is a homocentric square-shaped monolithic protective film, and a width of the homocentric square-shaped monolithic protective film to be used on the edges and side surfaces of the thermally conductive graphene pad body in the direction perpendicular to the graphene orientation and on the application substrate is equal to the width of the thermally conductive graphene pad body to be bordered with the protective film + the thickness of the thermally conductive graphene pad body + the lamination width of the protective film to the application substrate.

By covering the upper and lower surfaces and side surfaces of the thermally conductive graphene pad at the same time with the monolithic protective film, the thermally conductive graphene pad bordered with the protective film according to the present disclosure achieves integral structure and high mechanical strength, and the process is simple.

When deformation occurs to the thermally conductive graphene pad bordered with the protective film according to the present disclosure, the protective film is first stressed, because the tensile strength of the protective film is higher than that of the thermally conductive graphene pad body, the elongation of the protective film is smaller than but matches that of the thermally conductive graphene pad, and the protective film has better adhesion. Moreover, the protective film is not likely to peel off from the thermally conductive graphene pad, since the protective film used in the present disclosure has small thickness and the binding force of the protective film to the thermally conductive graphene pad body 1 is high, which is greater than 100 g/25 mm. Furthermore, the protective film of the present disclosure is a monolithic protective film, which can deform with the deformation of the thermally conductive graphene pad body, neither peeling-off nor delamination occurs between the thermally conductive graphene pad body and the protective film. The thermally conductive graphene pad bordered with the monolithic protective film according to the present disclosure achieves improved strength while effectively ensuring a thermally conductive effect.

According to the present disclosure, the use of a monolithic protective film to cover the thermally conductive graphene pad body can achieve full coverage of the edges of front and back surfaces and the side surfaces of the thermally conductive graphene pad body, and covered regions of the upper and lower surfaces intervene in an interface between a heat source and a heatsink during an application process, such that the thermally conductive graphene pad body is completely scaled to avoid falling of slags from the thermally conductive graphene pad body.

Enhanced strength: Compared with the uncovered thermally conductive graphene pad body in Comparative Example 1, the thermally conductive graphene pad body 1 bordered with the monolithic protective film in Example 2 has the weak edge strength increased from 51 KPa to more than 300 KPa, and has the maximum horizontal creep reduced from 5 mm to less than 0.5 mm, under the compressive deformation of 50%.

High reliability: the monolithic protective film 2 may deform with the deformation of the thermally conductive graphene pad body 1, which is not prone to delamination.

The present disclosure connects the thermally conductive graphene pad to the application substrate by means of the protective film, thereby achieving a positioning capability to facilitate automated mounting while preventing the thermally conductive graphene pad from cracking or curling at an edge in case of transverse shear.

In some embodiments, the thermally conductive graphene pad body is formed by a horizontally arranged graphene structure.

In some embodiments, the protective film includes one or more layers of protective film.

To solve the technical problems described above, the present disclosure further discloses a thermally conductive graphene pad bordered with a protective film, including a thermally conductive graphene pad body, a first protective film, and a second protective film, wherein the first protective film sequentially covers edges of an upper surface of the thermally conductive graphene pad body, side surfaces of the thermally conductive graphene pad body, and edges of a lower surface of the thermally conductive graphene pad body; the second protective film covers an upper surface of the first protective film, and extends by a portion to cover the thermally conductive graphene pad body; and the second protective film covers side surfaces of the first protective film and an upper surface of an application substrate.

In some embodiments, the first and second protective films are both monolithic protective films.

To solve the technical problems described above, the present disclosure further discloses a heatsink, including a heatsink and a thermally conductive pad covering a bottom surface of the heatsink, wherein the thermally conductive pad is the thermally conductive graphene pad bordered with the protective film as defined above.

To solve the technical problems described above, the present disclosure further discloses a chip packaging structure, including a semiconductor chip and a thermally conductive pad covering the semiconductor chip, wherein the thermally conductive pad is the thermally conductive graphene pad bordered with the protective film as defined above.

The thermally conductive graphene pad bordered with the protective film according to the present disclosure has enhanced structural strength, improved resistance to transverse shear, and adhesion, such that the thermally conductive graphene pad is endowed with repetitive adhesion, which ensures the structural integrity of the thermally conductive graphene pad during repetitive mounting, while avoiding the risk of slag falling that may occur to the thermally conductive graphene pad during repetitive mounting and placement.

### BRIEF DESCRIPTION OF DRAWINGS

FIG. 1a is a structural schematic diagram of a thermally conductive graphene pad bordered with a protective film according to Example 1 of the present disclosure;

FIG. 1b is a sectional view of FIG. 1a;

FIG. 2a is a structural schematic diagram of a thermally conductive graphene pad bordered with a monolithic protective film according to Example 2 of the present disclosure;

FIG. 2b is a sectional view of FIG. 2a;

FIG. 2c is a comparison diagram of a thermally conductive graphene pad body uncovered with a protective film before and after deformation, with the right figure in FIG. 2c showing a structural schematic diagram of the thermally conductive graphene pad body uncovered with the protective film before the deformation, and the left figure of FIG. 2c showing a structural schematic diagram of the thermally conductive graphene pad body uncovered with the protective film after the deformation;

FIG. 2d is a comparison diagram of a thermally conductive graphene pad body covered with a protective film according to Example 2 before and after deformation, with the right figure in FIG. 2d showing a structural schematic diagram of the thermally conductive graphene pad bordered with a monolithic protective film according to Example 2 before deformation, and the left figure in FIG. 2d showing a structural schematic diagram of the thermally conductive graphene pad bordered with the monolithic protective film according to Example 2 after deformation;

FIG. 2e is a schematic diagram of an application scenario of the thermally conductive graphene pad bordered with a monolithic protective film 2 according to Example 2;

FIG. 2f is a schematic diagram of an application scenario of a thermally conductive graphene pad bordered with a protective film according to Example 2A;

FIG. 2g is a schematic diagram of an application scenario of a thermally conductive graphene pad bordered with a protective film in another case according to Example 2B;

FIG. 3a is a structural schematic diagram of a thermally conductive graphene pad bordered with a monolithic protective film according to Example 3 of the present disclosure;

FIG. 3b is a sectional view of FIG. 3a;

FIG. 4a is a structural schematic diagram of a thermally conductive graphene pad bordered with a protective film according to Example 4 of the present disclosure;

FIG. 4b is a sectional view of FIG. 4a;

FIG. 5a is a structural schematic diagram of a thermally conductive graphene pad bordered with a protective film according to Example 5 of the present disclosure;

FIG. 5b is a sectional view of FIG. 5a.

### DETAILED DESCRIPTION OF THE EMBODIMENTS

In order to further set forth the technical means adopted by the present disclosure to achieve an intended purpose and the effects achieved, the specific embodiments, methods, steps, structures, features and effects of an anode material proposed based on the present disclosure are described in detail hereinafter in conjunction with the accompanying drawings and the preferred embodiments. The foregoing and other technical contents, features and effects of the present disclosure will be clearly presented in the following detailed description of the preferred embodiments with reference to the drawings. With the description of the specific embodiments, the technical means adopted by the present disclosure to achieve the intended purpose and the effects achieved can be deeply understood in detail. However, the accompanying drawings are only for reference and illustration purposes, and are not intended to limit the present disclosure.

The performance test methods for the following examples are as follows.

### 1. Tensile Strength:

Test method: GB/T 1040.2-2022; tensile speed: 300 mm/min; specimen width: 25 mm; specimen thickness: 0.3 mm. The thermally conductive graphene pad has an intra-plane graphene direction perpendicular to a specimen length direction.

Test instrument: universal tester, TSE254C.

### 2. Thermal Resistance (K*Cm²/W) at the Pressure of 10 PSI, 20 PSI, 30 PSI, and 40 PSI.

Test method: ASTM D5470; test temperature: 80° C.; test sample: dimensions: 25*25 mm, and thickness: 0.3 mm. The corresponding pressure is applied, and a thermal steady state is reached, thereby acquiring a corresponding thermal resistance value.

Test instrument: thermal resistance analyzer, LW-9389.

### 3. Creep Test:

Test method: Executive standard GB/T 20671.5-2020; test sample: dimensions: 25*25 mm, thickness: 2 mm. The compressive deformation of 50% is kept for 1 hour, the pressure is then removed, and the deformation dimension of the sample is measured.

Test instrument: universal tester, TSE254C.

### 4. Insertion and Extraction Endurance Test

Test method: Executive standard: EIA-364-13D-2007.

Insertion and extraction are carried out 50 times to detect the structural integrity of the thermally conductive pad in terms of defects such as damage, crack, slag falling and scratch.

Test instrument: HF-5001 insertion and extraction force tester.

### Example 1. Thermally Conductive Graphene Pad Bordered with Protective Film

In Example 1, a protective film covers the peripheries of the side surfaces of a thermally conductive graphene pad.

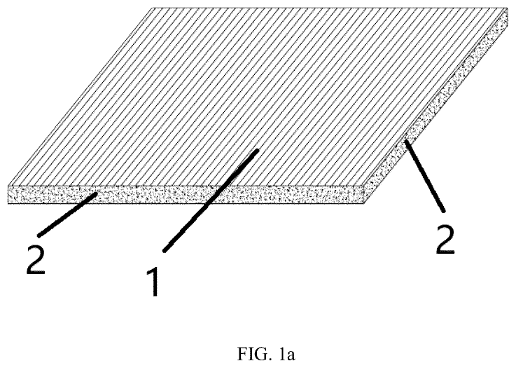

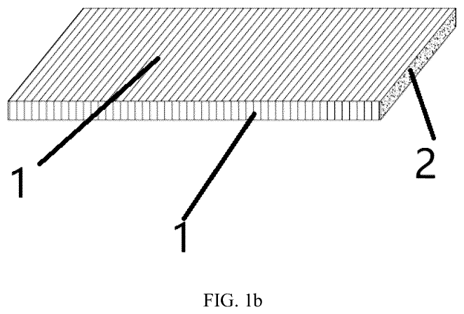

Referring to FIGS. 1a and 1b, a thermally conductive graphene pad bordered with a protective film includes a thermally conductive graphene pad body 1 and a protective film 2. The peripheries of the side surfaces of the thermally conductive graphene pad body 1 are covered by the protective film 2.

In this example, a process for preparing the thermally conductive graphene pad bordered with the protective film includes the following steps:

In step 1, a limiting device is attached to upper and lower surfaces of the thermally conductive graphene pad body 1, which has a thickness of 0.3 mm.

In step 2, the thermally conductive graphene pad body 1 with the limiting device attached to its upper and lower surfaces is cut according to the desired dimensions of a thermally conductive graphene pad.

In step 3, the peripheries of the side surfaces of the cut thermally conductive graphene pad body 1 with the limiting device attached is coated with a material (for example, polyurethane, polysiloxane, styrene-butadiene latex, paraffin, polyethylene terephthalate, epoxy resin, polyethylene, acrylic resin, or polyimide) capable of forming a protective film; the superfluous material is wiped away; and the material is cured to form the protective film 2 on the peripheries of the side surfaces of the thermally conductive graphene pad body 1.

In step 4, the limiting device is removed from the upper and lower surfaces of the thermally conductive graphene pad body 1 to obtain the thermally conductive graphene pad bordered with the protective film 2 covering the peripheries of the side surfaces.

### Comparative Example 1. Unbordered Thermally Conductive Graphene Pad (with the Thickness of 0.3 mm)

Based on tests, the unbordered thermally conductive graphene pad of Comparative Example 1 has a tensile strength of 51 Kpa.

TABLE 1
Tensile strength comparison between thermally conductive
graphene pads with protective film covering peripheries
of side surfaces in Example 1 and unbordered thermally
conductive graphene pad in Comparative Example 1

| Examples | Protective film | Tensile strength | |
|---|---|---|---|
| Example 1-1 | Polyurethane | 81 | KPa |
| Example 1-2 | Polysiloxane | 79 | KPa |
| Example 1-3 | Styrene-butadiene latex | 75 | KPa |
| Example 1-4 | Paraffin | 72 | KPa |
| Example 1-5 | Polyethylene terephthalate | 103 | KPa |
| Example 1-6 | Epoxy resin | 112 | KPa |
| Example 1-7 | Polyethylene | 98 | KPa |
| Example 1-8 | Acrylic resin | 114 | KPa |
| Example 1-9 | Polyimide | 132 | KPa |
| Comparative | None | 51 | Kpa |
| example 1-1 | | | |

The test data in Table 1 show that the tensile strength of the thermally conductive graphene pads with protective film covering the peripheries of the side surfaces in Example 1 is significantly improved. The technical solution disclosed in Example 1 is simple in process, easy to operate, and high in mass producibility, and can prevent graphene particles from falling off the thermally conductive graphene pad body.

### Example 2. Thermally Conductive Graphene Pad Bordered with Monolithic Protective Film

In Example 2, the edges of the upper surface of the thermally conductive graphene pad body, the edges of the lower surface of the thermally conductive graphene pad body, and the side surfaces of the thermally conductive graphene pad body are covered with the protective film.

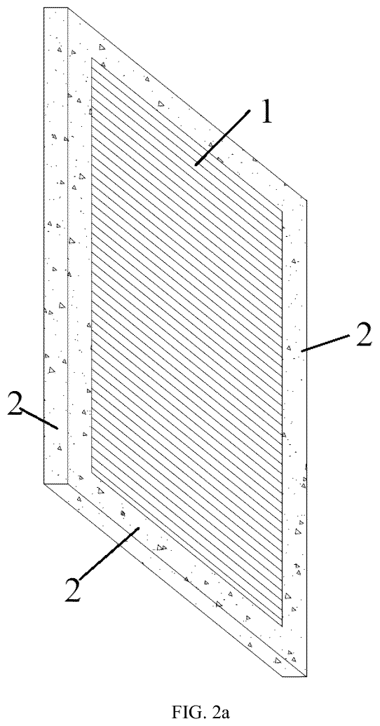

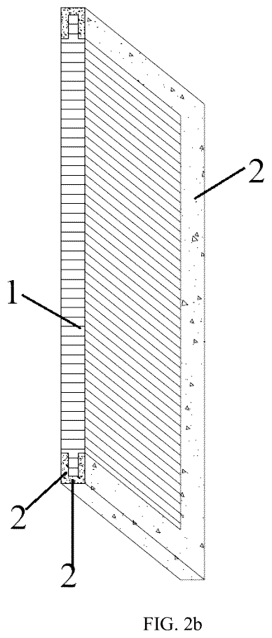

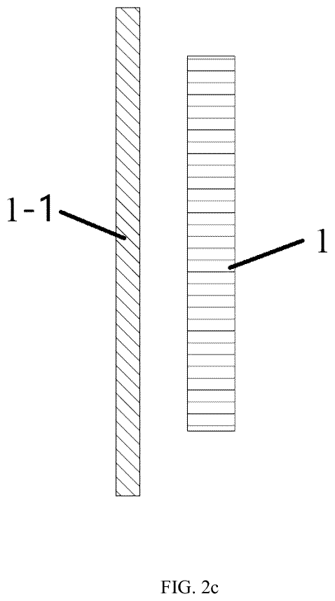

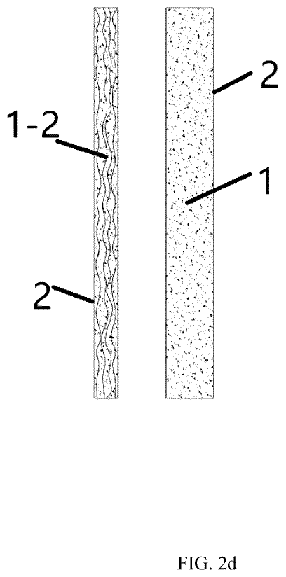

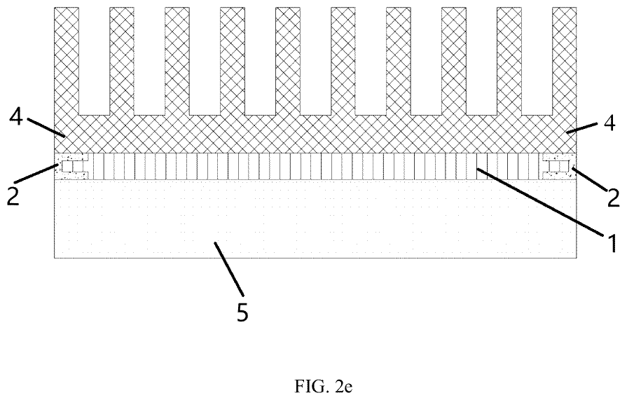

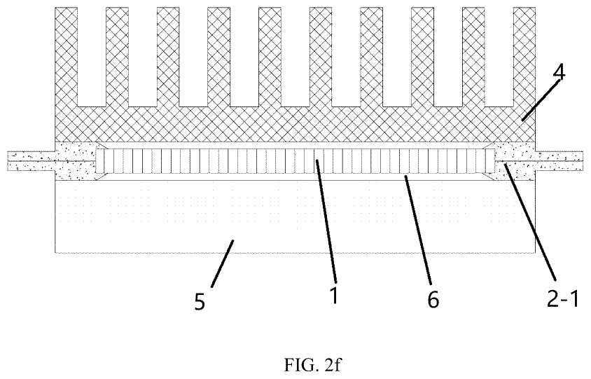

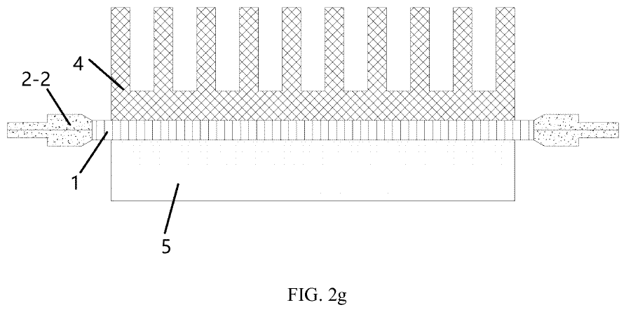

Referring to FIGS. 2a and 2b, Example 2 discloses a thermally conductive graphene pad bordered with a monolithic protective film, including a thermally conductive graphene pad body 1 and a protective film 2. The edges of an upper surface of the thermally conductive graphene pad body 1, the edges of a lower surface of the thermally conductive graphene pad body 1, and the side surfaces of the thermally conductive graphene pad body 1 are covered with the protective film 2; and the thermally conductive graphene pad body 1 includes longitudinally arranged graphene, which runs through the upper and lower surfaces of the thermally conductive graphene pad body 1 to form a thermally conductive continuous structure. The protective film 2 is a monolithic protective film 2. In this example, the edges of the upper surface of the thermally conductive graphene pad body 1 and the edges of the lower surface of the thermally conductive graphene pad body 1 are covered with the monolithic protective film 2 at a width of 0.2 mm.

This example discloses a preparation method for the thermally conductive graphene pad bordered with the monolithic protective film, which includes the following steps.
Step (1), preparing section A: performing die cutting according to a desired dimension to obtain a thermally conductive graphene pad.
centering and pressing a limiting device on upper and lower surfaces of the die-cut thermally conductive graphene pad to expose the thermally conductive graphene pad to be bordered with the protective film 2 to obtain the section A, wherein the area of the limiting device is smaller than that of the thermally conductive graphene pad.

The thermally conductive graphene pad body 1 to be bordered with the protective film 2 includes:
the edges of the upper surface of the thermally conductive graphene pad body 1,
the edges of the lower surface of the thermally conductive graphene pad body 1, and
the peripheries of the side surfaces of the thermally conductive graphene pad body 1.

The exposed thermally conductive graphene pad body 1 to be bordered with the protective film 2 is shaped as a homocentric square.
Step (2), preparing section B: cutting the protective film 2 with a release liner to acquire a frame of the protective film 2 having the shape and dimension matching the thermally conductive graphene pad body 1 to be bordered with the protective film 2.

In step (2), the protective film 2 exposed from the section B after cutting is a homocentric square-shaped monolithic protective film, the width of which is equal to the width of the thermally conductive graphene pad to be bordered with the protective film*2+ the thickness of the thermally conductive graphene pad. In this way, the protective film 2 of the section B may be used to implement the one-step coverage of the edges of upper and lower surfaces of the homocentric square-shaped thermally conductive graphene pad and the side surface of the thermally conductive graphene pad, thereby achieving convenience, swiftness and improved efficiency.

The width of the protective film 2 meets the following relational expression:
the width of the homocentric square-shaped protective film exposed from the section B=the width of the thermally conductive graphene pad body to be bordered with the protective film*2+ the thickness of the thermally conductive graphene pad body. During actual application, as long as this relational expression is met, the dimensions of the outer and inner frames of the cut protective film of the section B may be any value.

In this example, the thermally conductive graphene pad body 1 has a width of 25 mm and a thickness of 0.3 mm, and the thermally conductive graphene pad to be bordered with the protective film 2 has a width of 0.2 mm.

In this example, the width of the homocentric square-shaped protective film exposed from the section B is: 0.2 (i.e., the width of the thermally conductive graphene pad body 1 to be bordered with the protective film)*2 mm+0.3 mm (i.e., the thickness of the thermally conductive graphene pad body 1)=0.7 mm.

In this example, the cut protective film 2 of the section B has the outer frame with the dimensions of 26 mm*26 mm, and the inner frame with the dimensions of 24.6 mm*24.6 mm. This can ensure that the width of the homocentric square-shaped protective film is 0.7 mm, thereby achieving one-step coverage of the edges of the upper surface of the thermally conductive graphene pad body 1, the edges of the lower surface of the thermally conductive graphene pad body 1, and the peripheries of the side surfaces of the thermally conductive graphene pad body 1 by using the protective film 2.
Step (3), covering the edges of one surface of the thermally conductive graphene pad body the frame of the protective film 2:

transferring the section B to one surface of the section A to allow a surface of the protective film 2 of the section B to face one surface of the exposed thermally conductive graphene pad body 1 of the section A, and aligning and laminating the protective film 2 of the section B to the section A in a manner of exposing the thermally conductive graphene pad body 1 to be bordered with the protective film 2, thereby neatly and closely covering the exposed homocentric square-shaped region of the thermally conductive graphene pad body 1 of the section A with the protective film 2.
Step (4), covering the side surfaces and the edges of the other surface of the thermally conductive graphene pad body 1 with the frame of the protective film 2:

pressing down and laminating the protective film 2 to the section A in a manner of exposing the side surfaces of the thermally conductive graphene pad body 1 to be bordered with the protective film 2; and then, bending the protective film 2 towards the other surface of the thermally conductive graphene pad body 1 to laminate to the other surface of the thermally conductive graphene pad body 1 of the section A.
Step (5), applying a pressure to the protective film 2 to allow the protective film 2 to be completely laminated to the section A, thereby ensuring that the region of the thermally conductive graphene pad body 1 covered with the protective film 2 is as thick as a region of the thermally conductive graphene pad body 1 uncovered with the protective film 2, and the protective film 2 is free of bulges; removing the release liner; and removing the limiting device from the section A to obtain the thermally conductive graphene pad bordered with the monolithic protective film. The edges of the upper and lower surfaces and the side surfaces of the thermally conductive graphene pad bordered with the monolithic protective film are covered by the protective film 2, which effectively improves the strength of the thermally conductive graphene pad. During application, the region on the upper surface of the thermally conductive graphene pad body 1 covered by the protective film 2 and the region on the lower surface of the thermally conductive graphene pad body 1 covered by the protective film 2 intervene in the interface between a heat source 5 and a heatsink 4. The thermally conductive graphene pad bordered with the monolithic protective film is completely sealed between the heat source 5 and the heatsink 4, such that no air layer exists between the thermally conductive graphene pad bordered with the monolithic protective film and the heat source 5 and between the thermally conductive graphene pad bordered with the monolithic protective film and the heatsink 4, which effectively ensures the thermal conductive performance of the thermally conductive graphene pad bordered with the monolithic protective film.

The area of one surface of the thermally conductive graphene pad body 1 covered by the protective film 2 accounts for 0.0%-30% of the area of one surface of the thermally conductive graphene pad body 1. For example, the ratio of the area of one surface of the thermally conductive graphene pad body 1 covered by the protective film 2 to the area of one surface of the thermally conductive graphene pad body 1 may also be 3.17%, 4.74%, 7.84%, 15.36%, 19.72%, 29.44% or the like, the details of which can be found in Table 2.

The ratio of the area of one surface of the thermally conductive graphene pad body 1 covered by the protective film 2 to the area of the surface of the thermally conductive graphene pad body 1 is calculated, by way of example, with a method as follows.

In Example 2-1 in Table 2, the width of the edge of one surface of the thermally conductive graphene pad body 1 covered by the monolithic protective film 2 is 0.2 mm, so the area of the edge of one surface of the thermally conductive graphene pad body covered with the monolithic protective film 2 is:

25 mm*25 mm−24.6 mm*24.6 mm=19.84 mm².

In Example 2-1, the width of the thermally conductive graphene pad body is 25 mm, and the area of one surface of the thermally conductive graphene pad body is then 25 mm*25 mm=625 mm².

In Example 2-1, the ratio of the area of one surface of the thermally conductive graphene pad body 1 covered by the protective film 2 to the area of one surface of the thermally conductive graphene pad body 1 is:

19.84 mm²/625 mm²*100%=3.17%.

TABLE 2
Ratio of area of one surface of thermally conductive graphene pad body 1 covered by
protective film 2 to area of one surface of thermally conductive graphene pad body 1.

| | | | Width of | | | | Ratio of area of one |
|---|---|---|---|---|---|---|---|
| | Thickness | | thermally | | Dimensions | Dimensions | surface of thermally |
| | of | Width of | conductive | | of outer | of inner | conductive graphene pad |
| | thermally | thermally | graphene pad | | frame of | frame of | body covered by |
| | conductive | conductive | body to be | Protective | protective | protective | protective film to area of |
| | graphene | graphene | bordered with | film | film in | film in | one surface of thermally |
| | pad body | pad body | protective film | Thickness | section B | section B | conductive graphene pad |
| Examples | (mm) | (mm) | (mm) | (μm) | (mm) | (mm) | body (%) |
| Comparative | 0.3 | 25 | 0 | 0 | 0 | 0 | 0 |
| Example 1 | | | | | | | |
| Comparative | 2.0 | 25 | 0 | 0 | 0 | 0 | 0 |
| example 2 | | | | | | | |
| Example 2-1 | 0.3 | 25 | 0.2 | 1 | 26*26 | 24.6*24.6 | 3.17% |
| Example 2-2 | 0.3 | 25 | 0.3 | 1 | 26.2*26.2 | 24.4*24.4 | 4.74% |
| Example 2-3 | 0.3 | 25 | 0.5 | 1 | 26.6*26.6 | 24.0*24.0 | 7.84% |
| Example 2-4 | 0.3 | 25 | 1.0 | 1 | 27.6*27.6 | 23.0*23.0 | 15.36% |
| Example 2-5 | 0.3 | 25 | 1.3 | 1 | 28.2*28.2 | 22.4*22.4 | 19.72% |
| Example 2-6 | 0.3 | 25 | 2.0 | 1 | 29.6*29.6 | 21.0*21.0 | 29.44% |
| Example 2-7 | 0.3 | 25 | 0.3 | 3 | 26.2*26.2 | 24.4*24.4 | 4.74% |
| Example 2-8 | 0.3 | 25 | 0.3 | 5 | 26.2*26.2 | 24.4*24.4 | 4.74% |
| Example 2-9 | 0.3 | 25 | 0.3 | 10 | 26.2*26.2 | 24.4*24.4 | 4.74% |
| Example 2-10 | 0.3 | 25 | 0.3 | 20 | 26.2*26.2 | 24.4*24.4 | 4.74% |
| Example 2-11 | 0.3 | 25 | 0.3 | 30 | 26.2*26.2 | 24.4*24.4 | 4.74% |
| Example 2-12 | 2.0 | 25 | 0.3 | 1 | 29.6*29.6 | 24.4*24.4 | 4.74% |

TABLE 3
Comparison of thermal resistance and tensile strength in case of
different ratios of area of one surface of thermally conductive
graphene pad body 1 covered by protective film 2 to area of one
surface of thermally conductive graphene pad body 1 in Example 2

| | Thermal resistance (Kcm²/W) | | | | Tensile |
|---|---|---|---|---|---|
| Examples | 10 PSI | 20 PSI | 30 PSI | 40 PSI | strength (Kpa) |
| Comparative | 0.097 | 0.086 | 0.078 | 0.074 | 51 |
| Example 1-1 | | | | | |
| Example 2-1 | 0.099 | 0.087 | 0.079 | 0.075 | 251 |
| Example 2-2 | 0.104 | 0.091 | 0.084 | 0.080 | 322 |
| Example 2-3 | 0.108 | 0.096 | 0.088 | 0.085 | 497 |
| Example 2-4 | 0.150 | 0.134 | 0.125 | 0.120 | 838 |
| Example 2-5 | 0.164 | 0.147 | 0.137 | 0.132 | 997 |
| Example 2-6 | 0.201 | 0.182 | 0.170 | 0.165 | 1414 |
| Example 2-7 | 0.106 | 0.093 | 0.086 | 0.082 | 403 |
| Example 2-8 | 0.108 | 0.094 | 0.087 | 0.083 | 458 |
| Example 2-9 | 0.111 | 0.096 | 0.091 | 0.086 | 594 |
| Example 2-10 | 0.119 | 0.101 | 0.097 | 0.093 | 866 |
| Example 2-11 | 0.126 | 0.107 | 0.103 | 0.099 | 1138 |

In Example 2, the upper and lower surfaces and side surfaces of the thermally conductive graphene pad are covered with the monolithic protective film at the same time, thereby achieving integral structure and high mechanical strength, and the process is simple.

The protective film used in the present disclosure has a tensile strength greater than that of the thermally conductive graphene pad body. For example, in Example 2, the tensile strength of the protective film is greater than 10 MPa, and the tensile strength of the thermally conductive graphene pad body is 0.051 KPa. Under the same tensile force, the protective film used in the present disclosure has an elongation smaller than that of the thermally conductive graphene pad body. For example, the protective film in this example has an elongation of smaller than 1% under 200 Kpa; and the thermally conductive graphene pad body of the present disclosure has an elongation of 5-10% under 200 Kpa. The binding force of the protective film used in the present disclosure to the thermally conductive graphene pad is excellent, which is greater than 300 g/25 mm.

Referring to FIG. 2c and in combination with Table 4, the right figure in FIG. 2c is a structural schematic diagram of the thermally conductive graphene pad body 1 (with a thickness of 2 mm) uncovered with the protective film according to Example 2 before the deformation; and the left figure of FIG. 2c shows a thermally conductive graphene pad 1-1 obtained after the compressive deformation of 50% occurs to the thermally conductive graphene pad unbordered with the protective film according to Example 2. From FIG. 2c, it can be seen that the thermally conductive graphene pad 1-1 subjected to the compressive deformation of 50% becomes longer along the graphene arrangement direction as compared to the case before compression. Based on tests, the maximum horizontal creep of the thermally conductive graphene pad body 1 (with the thickness of 2 mm) uncovered by the protective film according to Example 2 is 5 mm.

Referring to FIG. 2d and in combination with Table 4, the right figure in FIG. 2d is a structural schematic diagram of the thermally conductive graphene pad bordered with the monolithic protective film according to Example 2-12 before the deformation; and the left figure of FIG. 2d is a structural schematic diagram of the thermally conductive graphene pad 1-2 obtained after the compressive deformation of 50% occurs to the thermally conductive graphene pad bordered with the monolithic protective film according to Example 2-12. From FIG. 2d, it can be seen that the thermally conductive graphene pad body 1 shows a little change in length along the graphene arrangement direction after the thermally conductive graphene pad bordered with the monolithic protective film according to Example 2 is deformed. Based on tests, the maximum horizontal creep of the thermally conductive graphene pad bordered with the monolithic protective film according to Example 2-12 is 0.4 mm.

When deformation occurs to the thermally conductive graphene pad bordered with the monolithic protective film according to the Example 2-12, the thermally conductive graphene pad body is first stressed, because the tensile strength of the protective film 2 is higher than that of the thermally conductive graphene pad body 1, and the elongation of the protective film 2 is smaller than that of the thermally conductive graphene pad body 1 under the same tensile force. Moreover, the protective film is not likely to peel off due to external pulling, since the protective film 2 used in the present disclosure has small thickness and the binding force of the protective film 2 to the thermally conductive graphene pad body 1 is high, which is greater than 300 g/25 mm. Furthermore, the protective film 2 of the present disclosure is a monolithic protective film 2, which may deform with the deformation of the thermally conductive graphene pad body 1, such that peeling-off and delamination do not occur between the thermally conductive graphene pad body 1 and the protective film 2. The thermally conductive graphene pad bordered with the monolithic protective film according to Example 2 achieves long service life and effectively ensures the thermally conductive effect.

TABLE 4
Comparison in maximum horizontal creep (mm) under a compression
of 50% between Example 2-12 and Comparative Example 2

| | Maximum horizontal creep (mm) |
|---|---|
| Examples | under a compression of 50% |
| Comparative Example 2 | 5 |
| Example 2-12 | 0.4 |

Referring to FIG. 2e, it is a schematic diagram of an application scenario of the thermally conductive graphene pad bordered with a monolithic protective film 2 according to Example 2. From FIG. 2e, it can be seen that the protective film 2 of the thermally conductive graphene pad bordered with the monolithic protective film according to Example 2 is a monolithic protective film 2, the region covered by the protective film 2 is as thick as the thermally conductive graphene pad body 1, and the protective film 2 does not bulge relative to the thermally conductive graphene pad body 1. During actual application, the thermally conductive graphene pad body 1 comes into full contact with the lower surface of the heatsink 4 and the upper surface of the heat source 5 (for example, a chip), without any gap and any air space, thereby effectively ensuring the thermally conductive performance of the thermally conductive graphene pad body 1.

In summary, the technical solution of Example 2 (including Example 2-1 to Example 2-12) has the following advantageous effects:

In Example 2, the monolithic protective film 2 is used to cover the thermally conductive graphene pad body 1; preferably, the ratio of the area of one surface of the thermally conductive graphene pad body covered by the protective film to the area of one surface of the thermally conductive graphene pad body is controlled to be less than 8%; the side surfaces of the thermally conductive graphene pad body 1 are completely covered by the protective film 2; meanwhile, the thickness of the protective film 2 is controlled below 5 μm, such that the region of the thermally conductive graphene pad body 1 covered by the protective film 2 is as thick as the region of the thermally conductive graphene pad body 1 uncovered by the protective film 2; here, the effect of the protective film 2 on the thermal resistance of the thermally conductive graphene pad body 1 is less than or equal to 0.01 Kcm²/W, which is within the test error range; and thus, the risk of slag falling from the thermally conductive graphene pad body 1 is completely eliminated on the premise that the effect on the thermal resistance of the thermally conductive graphene pad body 1 is negligible.

Enhanced strength: Compared with the uncovered thermally conductive graphene pad body in Comparative Example 1, the thermally conductive graphene pad body 1 bordered with the monolithic protective film in Example 2 has the weak edge strength increased from 51 KPa to more than 300 KPa, and has the maximum horizontal creep reduced from 5 mm to less than 0.5 mm, under the compressive deformation of 50%.

High reliability: the monolithic protective film 2 may deform with the deformation of the thermally conductive graphene pad body 1, to thereby prevent the thermally conductive graphene pad body 1 from delamination.

### Example 2A

### Preparation Method of Example 2A

the thermally conductive graphene pad body 1 is placed in a covering frame 2-1, with the thermally conductive graphene pad body 1 at a thickness of 0.3 mm, the covering frame 2-1 at a thickness of 0.05 mm, and a gap with a height of 0.1 mm existing between the thermally conductive graphene pad body 1 and the covering frame 2-1; a binder is injected, by a dispenser, into the gap between the covering frame 2-2 and the thermally conductive graphene pad body 1; and then, the binder dispensed to the thermally conductive graphene pad body 1 is cured.

Referring to FIG. 2f, it is a schematic diagram of an application scenario of a thermally conductive graphene pad bordered with a protective film according to Example 2A. From FIG. 2f, it can be seen that the thermally conductive graphene pad body 1 according to Example 2A is placed in the covering frame 2-1; a gap exists between the covering frame 2-1 and the thermally conductive graphene pad body 1, and is filled with a binder to thus connect the covering frame 2-1 with the thermally conductive graphene pad body 1; and in an application scenario of long-term pressure and high temperature, once the binder undergoes an aging failure, there is a risk that the covering frame 2-1 peels off from the thermally conductive graphene pad body 1, losing the effect of enhancing the structure of the thermally conductive graphene pad body 1. In Example 2A, the width of the covering frame 2-1 exceeds that of the graphene pad body 1, a space needs to be reserved for the covering frame 2-1 by an electronic device, which is not conducive to the miniaturized design of the chip 4. Although the thickness of the covering frame 2-1 itself is less than that of the thermally conductive graphene pad body 1, the total thickness of the bordered region after covering exceeds that of the thermally conductive graphene pad body 1. During the actual application, the structure of Example 2A leads to a suspended state of the thermally conductive graphene pad body 1 in particular in a low-pressure condition, such that the thermally conductive graphene pad body cannot come into direct contact with the upper surface of the heat source 5 (for example, a chip) and the lower surface of the heatsink 4 due to an air space 6, which greatly affects the thermally conductive performance of the thermally conductive graphene pad body 1.

### Example 2B

Referring to FIG. 2g, in Example 2B, the covering frame 2-2 does not intervene between the heat source 5 and the heatsink 4. During actual application, the structure of Example 2B has the difficulty in positioning; meanwhile, some regions of the thermally conductive graphene pad body 1 are not protected by the covering frame 2-2 and the upper and lower interfaces of the heat source 5 and the heatsink 4; the thermally conductive graphene pad body 1 undergoes the risk of damage and slag falling during actual application, such that the falling electroconductive graphene particles may easily cause a short circuit with the heat source 5 (for example, a chip) during application; and meanwhile, the covering frame 2-2 and the thermally conductive graphene pad body 1 are connected by means of the binder, and in an application scenario of long-term pressure and high temperature, once the binder undergoes an aging failure, there is a risk that the covering frame 2-2 peels off from the thermally conductive graphene pad body 1, losing the effect of enhancing the structure of the thermally conductive graphene pad body 1.

The preparation method of Example 2B is the same as that of Example 2A.

### Example 3. Thermally Conductive Graphene Pad Bordered with Monolithic Protective Film

The thermally conductive graphene pad bordered with the monolithic protective film according to Example 3 is resistant to transverse shear.

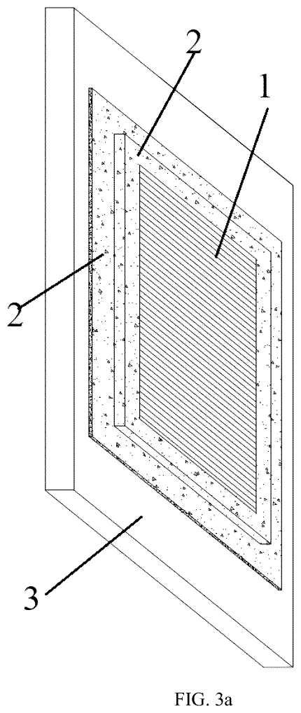

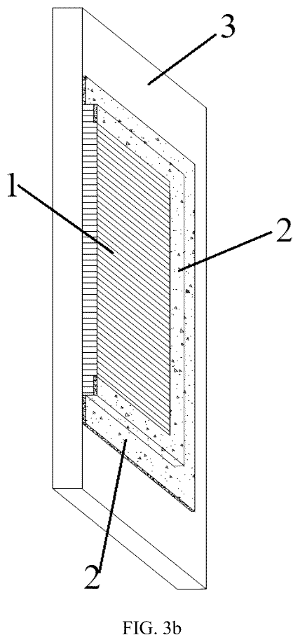

Referring to FIGS. 3a and 3b, Example 3 differs from Example 2 only in that the edges of one surface of and the side surfaces of the thermally conductive graphene pad body 1 are covered by the protective film 2. The other surface of the thermally conductive graphene pad body 1 is not covered by the protective film 2, but directly laminated to the application substrate 3, for example, by means of the protective film 2, during application.

The overall width of the homocentric square-shaped monolithic protective film 2 is equal to the width of the thermally conductive graphene pad to be bordered with the protective film 2+ the thickness of the thermally conductive graphene pad + the lamination width of the protective film 2 to the application substrate 3.

In this example, the width of the thermally conductive graphene pad is 25 mm; the lamination width of the protective film 2 to the thermally conductive graphene pad is 1 mm; the thickness of the thermally conductive graphene pad is 0.3 mm; and the lamination width of the protective film 2 to the application substrate 3 is 1 mm.

The overall width of the homocentric square-shaped monolithic protective film 2 is: 1 mm (i.e. the width of the thermally conductive graphene pad to be bordered with the protective film 2)+0.3 mm (i.e., the thickness of the thermally conductive graphene pad)+1 mm (the lamination width of the protective film 2 to the application substrate 3)=2.3 mm. The surface of the thermally conductive graphene pad and the surface of the application substrate 3 are completely fixed together by using the protective film 2.

In step 4, the section B obtained after cutting has an outer frame with the dimensions of 27.6 mm*27.6 mm, and an inner frame with the dimensions of 23 mm*23 mm. The inner and outer frames are both cut through to form the homocentric square-shaped monolithic protective film 2.

In step (4), the protective film 2 is pressed down and laminated to the section A in a manner of exposing the side surfaces of the thermally conductive graphene pad body 1 to be bordered with the protective film 2, and then the protective film 2 is bent outwards to keep parallel to the surface of the application substrate 3, and then laminated to the surface of the application substrate 3.

In this example, the thermally conductive graphene pad body 1 has a width of 25 mm and a thickness of 0.3 mm; the thermally conductive graphene pad body 1 to be bordered with the protective film 2 has a width of 1 mm; and the lamination width of the protective film 2 to the application substrate 3 is 1 mm. The surface of the thermally conductive graphene pad body 1 and the surface of the application substrate 3 are completely fixed together by using the protective film 2.

In Example 3, the width of the homocentric square-shaped monolithic protective film 2 is: 1 mm (i.e., the width of the thermally conductive graphene pad body 1 to be bordered with the protective film 2)+0.3 mm (i.e., the thickness of the thermally conductive graphene pad body 1)+1 mm (i.e., the lamination width of the protective film 2 to the application substrate 3)=2.3 mm.

The thermally conductive graphene pad bordered with the monolithic protective film according to Example 3 is subjected to the insertion and extraction endurance test, and endures more than 50 times of insertion and extraction. Based on one maintenance per year for a device, the thermally conductive graphene pad bordered with the monolithic protective film according to Example 3 has a service life of at least 50 years. However, the unbordered thermally conductive graphene pad in Comparative Example 1 is damaged after 1-2 times of insertion and extraction.

In Example 3, the protective film 2 is used to cover the surface of the thermally conductive graphene pad body 1 and the surface of the application substrate 3 at the same time, which avoids slag falling from the thermally conductive graphene pad during application while providing initial adhesion, thereby achieving convenience in mounting. The monolithic protective film 2 tightly binds the thermally conductive graphene pad body 1 to the application substrate 3 together, and meanwhile, a transition layer of the protective film is formed on upper surfaces of the thermally conductive graphene pad body 1 and the application substrate 3, such that the protective film 2 with excellent strength and low friction coefficient can avoid edge curling or damage of the thermally conductive graphene pad body 1 in case of transverse shear. In Example 3, the thermally conductive graphene pad is connected to the application substrate by means of the protective film, thereby achieving a positioning capability to facilitate automated mounting while preventing the thermally conductive graphene pad from cracking or curling at an edge in case of transverse shear.

### Example 4. Thermally Conductive Graphene Pad Bordered with Monolithic Protective Film

The thermally conductive graphene pad bordered with the monolithic protective film according to Example 4 is adjustable in mounted position.

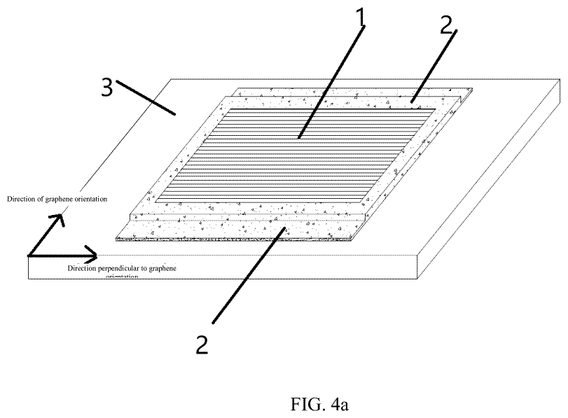

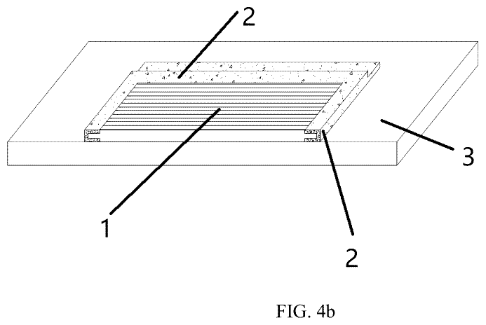

Referring to FIGS. 4a and 4b, in this example, the direction of graphene orientation refers to the direction in which graphene layers are stacked in the thermally conductive graphene pad body 1. In Example 4, the two edges of the thermally conductive graphene pad body 1 in the direction of graphene orientation are covered as Example 2. That is, for the two edges of the thermally conductive graphene pad body 1 in the direction of graphene orientation, the thermally conductive graphene pad body 1 is bordered with the protective film 2 at:
the upper surface of the thermally conductive graphene pad body 1 at the edges in the direction of the graphene orientation;
the lower surface of the thermally conductive graphene pad body 1 at the edges in the direction of the graphene orientation; and
and the two side surfaces of the thermally conductive graphene pad body 1 in the direction of the graphene orientation.

For the two edges of the thermally conductive graphene pad body 1 in the direction of the graphene orientation, the width of the homocentric square-shaped monolithic protective film in the direction of the graphene orientation is equal to the width of the thermally conductive graphene pad body 1 to be bordered with the protective film*2+ the thickness of the thermally conductive graphene pad body 1.

The edges of the thermally conductive graphene pad body 1 in the direction perpendicular to the graphene orientation are covered as Example 3. That is, for the two edges of the thermally conductive graphene pad body 1 in the direction perpendicular to the graphene orientation, the thermally conductive graphene pad body 1 is bordered with the protective film 2 at:
the upper surface of the thermally conductive graphene pad body 1 at the edges in the direction perpendicular to the graphene orientation;
and the two side surfaces of the thermally conductive graphene pad body 1 in the direction perpendicular to the graphene orientation; and
the lower surface of the thermally conductive graphene pad body 1 at the edges in the direction perpendicular to the graphene orientation is laminated to the application substrate 3.

The width of the homocentric square-shaped monolithic protective film 2 to be used on the edges and side surfaces of the thermally conductive graphene pad body 1 in the direction perpendicular to the graphene orientation and on the application substrate 3 is equal to the width of the thermally conductive graphene pad body 1 to be bordered with the protective film 2+ the thickness of the thermally conductive graphene pad body 1+ the lamination width of the protective film 2 to the application substrate 3.

In Example 4, the width of the thermally conductive graphene pad body 1 is 25 mm; the width of the thermally conductive graphene pad body 1 covered by the protective film 2 is 0.5 mm; the thickness of the thermally conductive graphene pad body 1 is 0.3 mm; and the lamination width of the protective film 2 to the application substrate 3 is 1 mm.

The width of the homocentric square-shaped monolithic protective film 2 in the direction of the graphene orientation is: 0.5 mm (i.e., the width of the thermally conductive graphene pad body 1 to be bordered with the protective film 2)*2+0.3 mm (the thickness of the thermally conductive graphene pad body 1)=1.3 mm; and the width of the homocentric square-shaped monolithic protective film 2 in the direction perpendicular to the graphene orientation is: 0.5 mm (i.e., the width of the thermally conductive graphene pad body 1 to be bordered with the protective film 2)+0.3 mm (i.e., the thickness of the thermally conductive graphene pad body 1)+1 mm (the lamination width of the protective film 2 to the application substrate 3)=1.8 mm.

In step 4, the section B obtained after cutting has an outer frame with the dimensions of 26.6 mm*27.6 mm, and an inner frame with the dimensions of 24 mm*24 mm. The inner and outer frames are both cut through to form the homocentric square-shaped monolithic protective film 2. In this example, the homocentric square-shaped monolithic protective film 2 has a square inner frame and a rectangular outer frame.

The edges and side surfaces of the thermally conductive graphene pad body 1 in the direction of the graphene orientation are covered by the process of Example 2; and two wide edges of the outer frame of the protective film 2 are used to cover the edges and side surfaces of the thermally conductive graphene pad body 1 in the direction of the graphene orientation.

The edges and side surfaces of the thermally conductive graphene pad body 1 in the direction perpendicular to the graphene orientation and the application substrate 3 are covered by the process of Example 3; and two long edges of the outer frame of the protective film 2 are used to cover the edges and side surfaces of the thermally conductive graphene pad body 1 in the direction perpendicular to the graphene orientation and the application substrate 3. The process is specifically as follows.

A preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body 1 to expose the thermally conductive graphene pad body to be bordered with the protective film to obtain the section A, wherein the area of the limiting device is smaller than or equal to that of the thermally conductive graphene pad body 1;
step (2), preparing section B: prefabricating the protective film on a release liner, cutting the protective film with the release liner to acquire a protective film frame having a shape and dimension matching the thermally conductive graphene pad body to be bordered with the protective film;
step (3), for two edges of the thermally conductive graphene pad body 1 in a direction of a graphene orientation, sequentially covering, with the protective film:
the upper surface of the thermally conductive graphene pad body 1 at the edges in the direction of the graphene orientation;
side surfaces of the thermally conductive graphene pad body 1 in the direction of the graphene orientation,
and a lower surface of the thermally conductive graphene pad body 1 at the edges in the direction of the graphene orientation;
step (4), for two edges of the thermally conductive graphene pad body 1 in a direction perpendicular to the graphene orientation, sequentially covering, with the protective film:
the upper surface of the thermally conductive graphene pad body 1 at the edges in the direction perpendicular to the graphene orientation;
and side surfaces of the thermally conductive graphene pad body 1 in the direction perpendicular to the graphene orientation, wherein
a lower surface of the thermally conductive graphene pad body 1 at the edges in the direction perpendicular to the graphene orientation is laminated to the application substrate; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

In Example 4, the protective film 2 is used to cover the upper and lower surfaces and side surfaces of the thermally conductive graphene pad body 1 at the edges in the weakest direction, i.e., the direction of the graphene orientation, so as to prevent the thermally conductive graphene pad body 1 from cracking and slag falling along the direction of the graphene orientation during application. Compared with Example 3, the binding of the protective film to the thermally conductive graphene pad body 1 is tighter and firmer, and the thermally conductive graphene pad can be repeatedly mounted and adjusted in mounted position. In Example 4, the protective film 2 at two sides in the direction perpendicular to the graphene orientation is laminated to the surface of the application substrate 3. Compared with Example 2, Example 4 provides the initial adhesion without affecting the thermal resistance of the thermally conductive graphene pad body 1, thereby facilitating the positioning and mounting of the thermally conductive graphene pad. The monolithic protective film 2 may tightly bind the thermally conductive graphene pad body 1 to the application substrate 3.

### Example 5. Thermally Conductive Graphene Pad Bordered with Protective Film

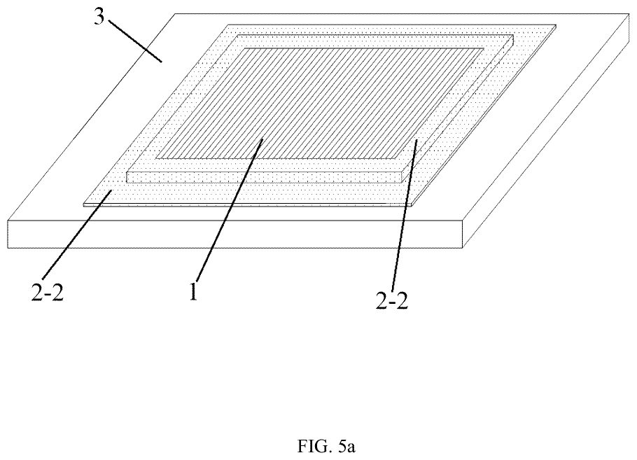

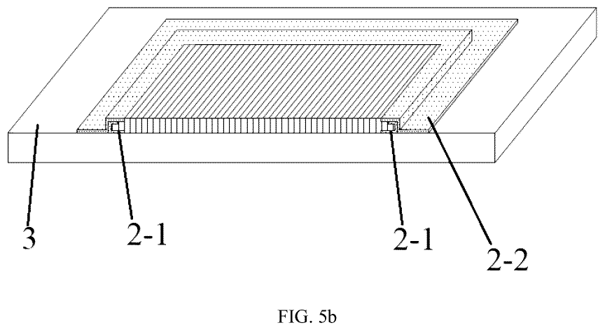

Example 5 is a solution improved based on Examples 2, 2A, 2B, and 3. Referring to FIGS. 5a and 5b, Example 5 provides a thermally conductive graphene pad bordered with a protective film. The thermally conductive graphene pad bordered with the protective film includes a thermally conductive graphene pad body 1, a first protective film 2-1, and a second protective film 2-2. The first protective film 2-1 sequentially covers the edges of an upper surface of the thermally conductive graphene pad body 1, the side surfaces of the thermally conductive graphene pad body 1, and the edges of a lower surface of the thermally conductive graphene pad body 1; the second protective film 2-2 covers the upper surface of the first protective film 2-1, and extends by a portion to cover the thermally conductive graphene pad body 1; and the second protective film 2-2 covers the side surfaces of the first protective film 2-1 and the upper surface of an application substrate 3.

The first protective film 2-1 and the second protective film 2-2 are both a monolithic protective film 2; and the thermally conductive graphene pad body 1 includes longitudinally arranged graphene, which runs through the upper and lower surfaces of the thermally conductive graphene pad body 1 to form a thermally conductive continuous structure.

In Example 5, the width of the thermally conductive graphene pad body is 25 mm; the thickness of the thermally conductive graphene pad body is 0.3 mm; the width of the edge of the upper surface of the thermally conductive graphene pad body 1 covered by the first protective film 2-1 is 0.3 mm; and the width of the edge of the lower surface of the thermally conductive graphene pad body 1 covered by the first protective film 2-1 is 0.5 mm.

In Example 5, the second protective film 2-2 covers the upper surface of the first protective film 2-1 and extends by a portion to cover the edge of the upper surface of the thermally conductive graphene pad body 1, with the width of 0.5 mm in total; and the lamination width of the second protective film 2-2 to the application substrate 3 is 1 mm.

Example 5 discloses a preparation method for the thermally conductive graphene pad bordered with the monolithic protective film, which includes the following steps.

First, the first protective film 2-1 is cut by referring to the preparation method for the thermally conductive graphene pad of Example 2.

The first protective film 2-1 is cut into the shape of homocentric squares. The width of the first protective film 2-1 after cutting is: 0.3 mm (i.e., the width of the upper surface of the thermally conductive graphene pad to be bordered by the protective film)+0.3 mm (the thickness of the thermally conductive graphene pad)+0.5 mm (the width of the lower surface of the thermally conductive graphene pad to be bordered with the protective film)=1.1 mm.

The first protective film 2-1 of B after cutting has the outer frame with the dimensions of 26.6 mm*26.6 mm and the inner frame with the dimensions of 24.4 mm*24.4 mm. The inner and outer frames are both cut through to form the homocentric square-shaped monolithic protective film 2-1.

The covering of the first protective film 2-1 is completed by referring to the preparation method of Example 2.

Then, the surface of the thermally conductive graphene pad covered by the first protective film 2-1 at the width of 0.3 mm is turned upwards, and the surface of the thermally conductive graphene pad covered by the first protective film 2-1 at the width of 0.5 mm is turned towards the application substrate 3. The second protective film 2-2 is cut and covered by referring to the steps of Example 3.

Referring to Example 3 for the cutting of the second protective film 2-2, the cut second protective film 2-2 has the outer frame with the dimensions of 27.6 mm*27.6 mm, and the inner frame with the dimensions of 24 mm*24 mm; and the inner and outer frames are both cut through to form the homocentric square-shaped monolithic second protective film 2-2. Then, the width of the cut second protective film 2-2 is: 0.5 mm (i.e. the width of the upper surface of the thermally conductive graphene pad to be bordered by the second protective film 2-2)+0.3 mm (i.e., the thickness of the thermally conductive graphene pad)+1.0 mm (i.e., the lamination width of the second protective film 2 to the application substrate)=1.8 mm.

After cutting, the upper surface of the first protective film 2-1, the side surfaces of the first protective film 2-1, and the application substrate 3 are sequentially covered by the second protective film 2-2 by referring to Example 3. The second protective film 2-2 covers the first protective film 2-1 while extending by a portion to cover the thermally conductive graphene pad body 1, such that the edges of the upper and lower surfaces of the thermally conductive graphene pad body 1 are covered at the same width, which is 0.5 mm in each case.

The thermally conductive graphene pad bordered with the monolithic protective film according to Example 5 combines the advantages of both the thermally conductive graphene pad bordered with the monolithic protective film according to Example 2 and the thermally conductive graphene pad bordered with the protective film according to Example 3, showing enhanced structural strength, improved resistance to transverse shear, and adhesion, such that the thermally conductive graphene pad is endowed with repetitive adhesion, which ensures the structural integrity of the thermally conductive graphene pad during repetitive mounting, while avoiding the risk of slag falling that may occur to the thermally conductive graphene pad during repetitive mounting and placement.

Described above are only preferred embodiments of the present disclosure, and are not intended to limit the present disclosure in any form. Although the present disclosure has been disclosed above by means of the preferred embodiments, which, however, are not intended to limit the present disclosure. Without departing from the scope of the technical solutions of the present disclosure, any person skilled in the art may change or modify the technical content disclosed above, through equivalent variations, into equivalent embodiments. Any simple alternation as well as equivalent variation and modification made to the embodiments above based on the technical essence of the present disclosure are also construed to fall within the scope of the technical solutions of the present disclosure.

What is claimed is:

1. A thermally conductive graphene pad bordered with a protective film, comprising a thermally conductive graphene pad body and the protective film covering the thermally conductive graphene pad body.

2. The thermally conductive graphene pad bordered with the protective film according to claim 1, wherein the thermally conductive graphene pad body comprises longitudinally arranged graphene, which runs through upper and lower surfaces of the thermally conductive graphene pad body to form a thermally conductive continuous structure.

3. The thermally conductive graphene pad bordered with the protective film according to claim 1, wherein the protective film is a monolithic protective film.

4. The thermally conductive graphene pad bordered with the protective film according to claim 3, wherein the protective film is a homocentric square-shaped monolithic protective film.

5. The thermally conductive graphene pad bordered with the protective film according to claim 1, wherein the protective film is formed from cured polyurethane, polysiloxane, styrene-butadiene latex, paraffin, polyethylene terephthalate, epoxy resin, polyethylene, acrylic resin, or polyimide.

6. The thermally conductive graphene pad bordered with the protective film according to claim 1, wherein edges of the upper surface of the thermally conductive graphene pad body, edges of the lower surface of the thermally conductive graphene pad body, and side surfaces of the thermally conductive graphene pad body are covered with the protective film.

7. The thermally conductive graphene pad bordered with the protective film according to claim 1, wherein edges of one surface of the thermally conductive graphene pad body and side surfaces of the thermally conductive graphene pad body are covered with the protective film, and the other surface of the thermally conductive graphene pad body is laminated to an application substrate by means of the protective film extending to a surface of the application substrate.

8. The thermally conductive graphene pad bordered with the protective film according to claim 1, wherein the protective film has a thickness in a range of 1-30 microns.

9. The thermally conductive graphene pad bordered with the protective film according to claim 1, wherein the area of one surface of the thermally conductive graphene pad body covered by the protective film accounts for 0.0%-30% of the area of the surface of the thermally conductive graphene pad body.

10. The thermally conductive graphene pad bordered with the protective film according to claim 1, wherein the region of the thermally conductive graphene pad body covered by the protective film is as thick as the region of the thermally conductive graphene pad body uncovered by the protective film.

11. The thermally conductive graphene pad bordered with the protective film according to claim 1, wherein the protective film has a tensile strength greater than that of the thermally conductive graphene pad body.

12. The thermally conductive graphene pad bordered with the protective film according to claim 1, wherein the protective film has an elongation smaller than that of the thermally conductive graphene pad body under the same tensile force.

13. The thermally conductive graphene pad bordered with the protective film according to claim 1, wherein a binding force of the protective film to the thermally conductive graphene pad body is greater than or equal to 100 g/25 mm.

14. A preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body to expose the thermally conductive graphene pad body to be bordered with the protective film to obtain the section A, wherein the area of the limiting device is smaller than or equal to that of the thermally conductive graphene pad body;
step (2), preparing section B: prefabricating the protective film on a release liner, cutting the protective film with the release liner to acquire a protective film frame having a shape and dimension matching the thermally conductive graphene pad body to be bordered with the protective film;
step (3), covering edges of one surface of the thermally conductive graphene pad body with the protective film frame;
step (4), covering side surfaces and edges of the other surface of the thermally conductive graphene pad body with the protective film frame; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

15. The preparation method for the thermally conductive graphene pad bordered with the protective film according to claim 14, wherein
the thermally conductive graphene pad body to be bordered with the protective film in step (1) comprises:
edges of the upper surface of the thermally conductive graphene pad body, and
peripheries of side surfaces of the thermally conductive graphene pad body; and
the protective film further covers a surface of the application substrate.

16. A preparation method for a thermally conductive graphene pad bordered with a protective film, comprising:
step (1), preparing section A: performing die cutting according to a desired dimension to obtain a thermally conductive graphene pad body, and
centering and pressing a limiting device on upper and lower surfaces of the die-cut thermally conductive graphene pad body to expose the thermally conductive graphene pad body to be bordered with the protective film to obtain the section A, wherein the area of the limiting device is smaller than or equal to that of the thermally conductive graphene pad body;
step (2), preparing section B: prefabricating the protective film on a release liner, cutting the protective film with the release liner to acquire a protective film frame having a shape and dimension matching the thermally conductive graphene pad body to be bordered with the protective film;
step (3), covering edges of one surface of the thermally conductive graphene pad body with the protective film frame;
step (4), covering side surfaces of the thermally conductive graphene pad body with the protective film frame, pressing down and laminating the protective film 2 to the section A in a manner of exposing side surfaces of the thermally conductive graphene pad body 1 to be bordered with the protective film, then bending the protective film outwards to keep parallel to a surface of an application substrate, and then laminating the protective film to the surface of the application substrate; and
step (5), applying a pressure to the protective film to allow a region of the thermally conductive graphene pad body covered with the protective film to be as thick as a region of the thermally conductive graphene pad body uncovered with the protective film, completely laminating the protective film to the section A, removing the release liner, and removing the limiting device from the section A to obtain the thermally conductive graphene pad bordered with the protective film.

17. The thermally conductive graphene pad bordered with the protective film according to claim 1, wherein the thermally conductive graphene pad body is formed by a horizontally arranged graphene structure.

18. The thermally conductive graphene pad bordered with the protective film according to claim 1, wherein the protective film comprises one or more layers of protective film.

19. A heatsink, comprising a heatsink and a thermally conductive pad covering a bottom surface of the heatsink, wherein the thermally conductive pad is the thermally conductive graphene pad bordered with the protective film according to claim 1.

20. A chip packaging structure, comprising a semiconductor chip and a thermally conductive pad covering the semiconductor chip, wherein the thermally conductive pad is the thermally conductive graphene pad bordered with the protective film according to claim 1.
